(19) United States
(12) Patent Application Publication
(10) Pub. No.: US 2011/0031984 A1
(43) Pub. Date: Feb. 10, 2011

(54) TEST APPARATUS

(75) Inventors: Yoshihiro HASHIMOTO, Saitama (JP); Yasuo FURUKAWA, Saitama (JP)

Correspondence Address: Masao Yoshimura, 333 W. El Camino Real, Suite 380, Sunnyvale, CA, 94087, US

(73) Assignee: ADVANTEST CORPORATION, Tokyo (JP)

(21) Appl. No.: 12/877,097

(22) Filed: Sep. 7, 2010

Related U.S. Application Data
(63) Continuation of application No. PCT/JP2010/001564, filed on Mar. 5, 2010.
Application No. PCT/JP2010/001564 is a continuation-in-part of application No. PCT/JP2009/003482, filed on Jul. 23, 2009.
Application No. PCT/JP2009/003482 is a continuation-in-part of application No. 12/603,350, filed on Oct. 21, 2009.
Application No. 12/603,350 is a continuation-in-part of application No. PCT/JP2010/001333, filed on Feb. 26, 2010.
Application No. PCT/JP2010/001333 is a continuation-in-part of application No. 12/502,946, filed on Jul. 14, 2009.

(51) Int. Cl. G01R 27/26

(52) U.S. Cl. 324/678

(57) ABSTRACT

Provided is a test apparatus that tests a device under test, comprising a power supply that generates power supplied to the device under test; a transmission path that transmits the power generated by the power supply to the device under test; a current measuring section that measures a digital waveform of load current supplied to the device under test via the transmission path, the digital waveform including a frequency component higher than a frequency corresponding to a product of an inductance component of the power supply and a capacitance component between the transmission path and a ground potential; and a judging section that judges acceptability of the device under test based on the digital waveform of the load current measured by the current measuring section.

### BACKGROUND

1. Technical Field

The present invention relates to a test apparatus.

2. Related Art

When testing a device under test such as a semiconductor circuit, a power supply apparatus that supplies current to the device under test sometimes cannot quickly follow fluctuation in the current consumed by the device under test. A known technique for solving this problem, as shown in Patent Document 1, involves providing a bypass capacitor to the power supply line near the device under test.

Patent Document 1: Japanese Patent Application Publication No. 2001-195139

Patent Document 2: U.S. Pat. No. 6,087,843

A bypass capacitor is provided that has a large capacitance, e.g. tens of μF, capable of following a large fluctuation in the power supply current. In order to measure a low current, such as standby current, it is necessary to measure a low output current of the power supply apparatus. In this case, there is a limit on the load capacitance connected to the power supply apparatus, and so a lead relay is provided to disconnect a high-capacitance bypass capacitor from the power supply line.

However, since there are structural limitations near the device under test, a lead relay cannot be provided there. As a result, the high-capacitance bypass capacitor cannot be provided near the device under test, and is instead provided at a distance from the device under test.

Therefore, the power supply line from the bypass capacitor to the device under test is lengthened, which increases the inductance component between the bypass capacitor and the device under test. As a result, it becomes difficult to supply high-frequency current from the bypass capacitor to the device under test.

Conventionally, the current supplied from the power supply or the high-capacitance bypass capacitor is measured, and so high-frequency components of the load current cannot be detected. Therefore, when the load current of the device under test fluctuates momentarily, the fluctuation of the load current cannot be detected, and so the acceptability of the device under test cannot be accurately judged.

### SUMMARY

Therefore, it is an object of an aspect of the innovations herein to provide a test apparatus, which is capable of overcoming the above drawbacks accompanying the related art. The above and other objects can be achieved by combinations described in the independent claims. The dependent claims define further advantageous and exemplary combinations of the innovations herein. According to a first aspect related to the innovations herein, one exemplary test apparatus may include a test apparatus that tests a device under test, comprising a power supply that generates power supplied to the device under test; a transmission path that transmits the power generated by the power supply to the device under test; a current measuring section that measures a digital waveform of load current supplied to the device under test via the transmission path, the digital waveform including a frequency component higher than a frequency corresponding to a product of an inductance component of the power supply and a capacitance component between the transmission path and a ground potential; and a judging section that judges acceptability of the device under test based on the digital waveform of the load current measured by the current measuring section.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a configuration of a test apparatus 100 according to an embodiment of the present invention, along with a device under test 200.

FIG. 2 shows an exemplary configuration of a circuit for measuring the current flowing through the transmission path 20.

FIG. 3 shows an exemplary current I1 measured by the power supply current measuring section 60 and an exemplary current I2 measured by the charge/discharge current measuring section 90.

FIG. 4 shows a load current IA calculated by the load current calculating section 98 and a current IB output by the power supply 30, when the device under test 200 performs a read operation.

FIG. 5 shows a load current IA calculated by the load current calculating section 98 and a current IB output by the power supply 30, when the device under test 200 performs a program operation.

FIG. 6 shows a load current IA calculated by the load current calculating section 98 and a current IB output by the power supply 30, when the device under test 200 performs an erase operation.

FIG. 7 shows an exemplary operation of the test apparatus 100.

FIG. 8 shows a measurement period of the judging section 130.

FIG. 9 shows another exemplary configuration of the charge/discharge current measuring section 90.

FIG. 10 shows an exemplary configuration of the switch 52.

FIG. 11 shows another exemplary configuration of a circuit for measuring the current flowing through the transmission path 20.

FIG. 12 shows the current flowing through the device under test 200 when the damping resistor 54 has a resistance value approximately equal to that of the resistor 58.

FIG. 13 shows the current flowing through the device under test 200 when the damping resistor 54 has a resistance value that is 20 times greater than that of the resistor 58.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

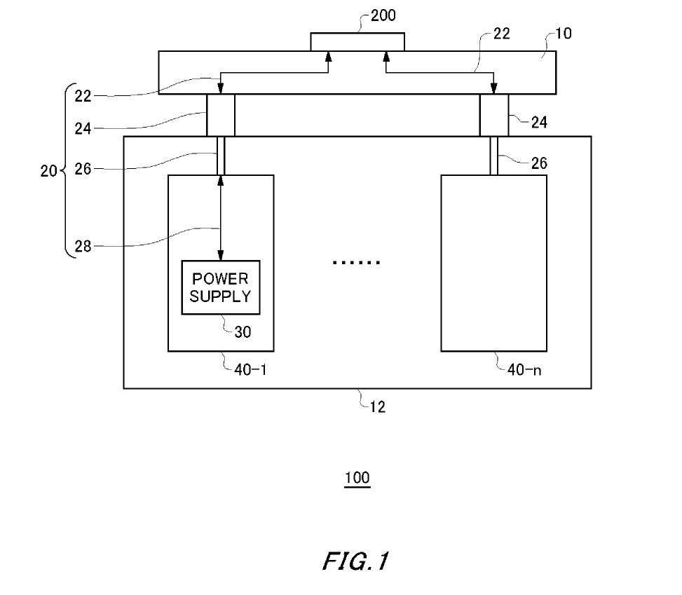

FIG. 1 shows a configuration of a test apparatus 100 according to an embodiment of the present invention, along with a device under test 200. The test apparatus 100 tests the device under test 200, which may be a semiconductor circuit, and includes a test board 10 and a test head 12.

The test board 10 electrically connects the device under test 200 to the test head 12. For example, the test board 10 may include a socket on which the device under test 200 is mounted to be electrically connected thereto and wiring that electrically connects the socket to the test head 12. Instead, the test board 10 may include a probe pin that contacts a terminal of the device under test 200 and wiring that electrically connects the probe pin to the test head 12.

The test head 12 generates a test signal and supply power or the like, and supplies the generated signals etc. to the device under test 200 via the test board 10. The test head 12 judges acceptability of the device under test 200 by measuring a prescribed characteristic of the device under test 200 when the test signal or the like is supplied thereto. For example, the test head 12 may measure a data pattern of a signal output by the device under test 200 or power consumed by the device under test 200.

The test head 12 of the present embodiment includes a plurality of test modules 40. Each test module 40 is electrically connected to the test board 10 via the connector 24. Each test module 40 may have a different function. For example, the test head 12 may include a test module 40 used to supply power, a test module 40 used for analog signals, and a test module 40 used for digital signals.

In the present embodiment, the test module 40-1 includes a power supply 30 for supplying power to the device under test 200. The power supply 30 is electrically connected to the device under test 200 via the transmission path 20.

The transmission path 20 transmits the power generated by the power supply 30 to the device under test 200. The transmission path 20 may include module wiring 28, a cable 26, a connector 24, and board wiring 22. The module wiring 28 is formed within the test module 40. The cable 26 connects the test module 40 to the connector 24. The board wiring 22 is formed on the test board 10.

The test apparatus 100 of the present invention measures the current consumed by the device under test 200 by measuring the current flowing through the transmission path 20. The test module 40-1 may judge the acceptability of the device under test 200 based on the result of the measurement of the current flowing through the transmission path 20.

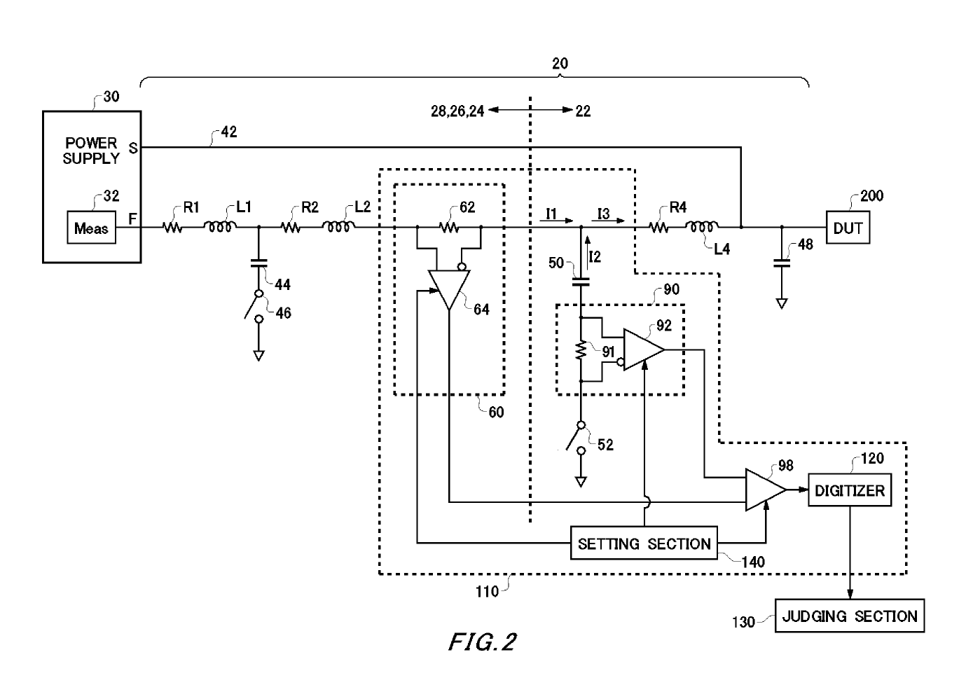

FIG. 2 shows an exemplary configuration of a circuit for measuring the current flowing through the transmission path 20. As described above, the power supply 30 is connected to the device under test 200 via the transmission path 20. The power supply 30 may include a low current measuring section 32 that measures a low current, such as the standby current of the device under test 200. The low current measuring section 32 may measure the current output by the power supply 30.

The test apparatus 100 includes a high-capacitance capacitor 44, a switch 46, a current measuring section 110, a low-capacitance capacitor 48, and a judging section 130. The current measuring section 110 includes an intermediate capacitor 50, a charge/discharge current measuring section 90, a switch 52, a power supply current measuring section 60, a load current calculating section 98, a digitizer 120, and a setting section 140. In FIG. 2, R1, R2, R4, L1, L2, and L4 represent resistance components and inductance components of the transmission path 20.

The high-capacitance capacitor 44 is connected between the transmission path 20 and a ground potential, at a position closer to the power supply 30 than the intermediate capacitor 50. The high-capacitance capacitor 44 of the present embodiment is provided between the ground potential and a position on the transmission path 20 closer to the power supply 30 than the connector 24, e.g. a position of the module wiring 28. The capacitance of the high-capacitance capacitor 44 may be greater than a maximum load capacitance allowed for the low current measuring section 32. This maximum load capacitance may be a specification value of the low current measuring section 32.

The switch 46 switches whether the high-capacitance capacitor 44 is connected between the module wiring 28 and the ground potential. The switch 46 may be a lead relay.

The low-capacitance capacitor 48 is positioned between the ground potential and the transmission path 20 at a position closer to the device under test 200 than the intermediate capacitor 50. The low-capacitance capacitor 48 of the present embodiment is provided on the test board 10 between the board wiring 22 and the ground potential. The capacitance of the low-capacitance capacitor 48 is less than the capacitance of the high-capacitance capacitor 44. The capacitance of the low-capacitance capacitor 48 may be less than the maximum load capacitance allowed for the low current measuring section 32.

The current measuring section 110 measures a digital waveform of the current supplied to the device under test 200 via the transmission path 20, and this digital waveform includes a frequency component that is higher than a frequency corresponding to the product of the inductance component L from the power supply 30 to the device under test 200 and the capacitance component C between the transmission path 20 and the ground potential. The inductance component L may include an inductance component connected to an output terminal in the power supply 30.

The inductance component L and the capacitance component C function as a low-pass filter inserted between the power supply 30 and the device under test 200, and so the frequency of the current flowing from the power supply 30 to the device under test 200 is limited to be no greater than a cutoff frequency corresponding to the product LC. However, in addition to the current supplied directly from the power supply 30 to the device under test 200, a high-frequency current is also supplied to the device under test 200 from a low-capacitance component.

Therefore, even though the current output by the power supply 30 is measured in the transmission path 20, only a component that is no greater than the cutoff frequency corresponding to LC in the current flowing through the device under test 200 can be measured. For this reason, the current measuring section 110 measures a digital waveform that includes the frequency component that is higher than the cutoff frequency corresponding to LC. More specifically, the current measuring section 110 measures these digital waveform including high-frequency components by measuring the charge/discharge current of the intermediate capacitor 50.

The intermediate capacitor 50 is provided between the ground potential and the transmission path 20 at a position between the high-capacitance capacitor 44 and the low-capacitance capacitor 48. The intermediate capacitor 50 is preferably connected to the transmission path 20 such that the distance between the intermediate capacitor 50 and the low-capacitance capacitor 48 is less than the distance between the intermediate capacitor 50 and the high-capacitance capacitor 44.

More specifically, the intermediate capacitor 50 is preferably positioned in a manner such that the inductance component L4, which is the inductance of the transmission path 20 between the intermediate capacitor 50 and the low-capacitance capacitor 48, is sufficiently less than the inductance component L2, which is the inductance of the transmission path 20 between the intermediate capacitor 50 and the high-capacitance capacitor 44. The intermediate capacitor 50 of the present embodiment is connected to the board wiring 22 of the test board 10 between the low-capacitance capacitor 48 and the connector 24.

By providing the intermediate capacitor 50 closer to the device under test 200 than the cable 26 and the connector 24, the inductance component L4 can be made sufficiently lower than the inductance component L2. As a result, the charge/discharge current of the intermediate capacitor 50 can follow a fluctuation in the current consumed by the device under test 200 relatively quickly.

The capacitance of the intermediate capacitor 50 may be greater than the capacitance of the low-capacitance capacitor 48 and less than the capacitance of the high-capacitance capacitor 44. The capacitance of the low-capacitance capacitor 48 may be approximately 1 μF and the capacitance of the intermediate capacitor 50 may be approximately 10 μF. The capacitance of the intermediate capacitor 50 may be greater than the maximum load capacitance allowed for the low current measuring section 32.

The switch 52 switches whether the intermediate capacitor 50 is connected between the module wiring 28 and the ground potential. The switch 52 may be smaller than the switch 46. For example, the switch 52 may be a semiconductor switch. When using the low current measuring section 32 to measure a low current such as the standby current of the device under test 200, the switch 46 and the switch 52 may disconnect the high-capacitance capacitor 44 and the intermediate capacitor 50 from between the transmission path 20 and the ground potential.

The power supply current measuring section 60 measures the current I1 flowing through the transmission path 20 in a region on the power supply 30 side of the intermediate capacitor 50. For example, the power supply current measuring section 60 may measure the current I1 flowing through the transmission path 20 between the high-capacitance capacitor 44 and the connector 24. The power supply current measuring section 60 may be provided in the test module 40.

The power supply current measuring section 60 of the present embodiment includes a first detection resistor 62 and a differential circuit 64. The first detection resistor 62 is provided on the transmission path 20 at a position closer to the power supply 30 than the connector 24, and causes a voltage drop corresponding to the current value flowing through the transmission path 20. The first detection resistor 62 may be provided on the module wiring 28, for example.

The differential circuit 64 functions as a first potential difference detecting section that detects a potential difference between the ends of the first detection resistor 62. The current I1 flowing through the first detection resistor 62 can be measured by multiplying the potential difference by the resistance value of the first detection resistor 62.

The configuration of the power supply current measuring section 60 is not limited to the example shown in FIG. 2. The power supply current measuring section 60 may include a current probe instead of the first detection resistor 62 and the differential circuit 64. The current probe may detect the current flowing through the transmission path 20 by converting the magnetic field caused by the current flowing through the transmission path 20 into voltage.

The charge/discharge current measuring section 90 measures the charge/discharge current I2 of the intermediate capacitor 50. The charge/discharge current measuring section 90 of the present embodiment includes a second detection resistor 91 and a differential circuit 92. The second detection resistor 91 is provided between the intermediate capacitor 50 and the switch 52, and causes a voltage drop corresponding to the charge/discharge current I2 of the intermediate capacitor 50.

The differential circuit 92 functions as a second potential difference detecting section that detects a potential difference between the ends of the second detection resistor 91. The current I2 flowing through the second detection resistor 91 can be measured by multiplying the potential difference by the resistance value of the second detection resistor 91.

The load current calculating section 98 calculates a load current I3 flowing through the device under test 200 based on the current I2 measured by the charge/discharge current measuring section 90. As described above, the intermediate capacitor 50 tracks fluctuation of the load current I3 more quickly than the power supply 30. Therefore, the current I2 includes a higher-frequency current component than the current I1. The load current calculating section 98 may calculate the current component that is higher than that of the current I1 within the load current I3 by measuring the current I2.

Instead, the load current calculating section 98 may calculate the load current I3 flowing through the device under test 200 based on the sum of the current I1 measured by the power supply current measuring section 60 and the current I2 measured by the charge/discharge current measuring section 90. As a result, the load current calculating section 98 can calculate a load current I3 that includes both a low-frequency component and a high-frequency component. The present example describes a case in which the load current calculating section 98 calculates the sum of the current I2 and the current I1.

The digitizer 120 converts, into a digital waveform, an analog waveform obtained as the sum of the current I1 measured by the power supply current measuring section 60 and an exemplary current I2 measured by the charge/discharge current measuring section 90. The digitizer 120 may include a memory for storing the resulting digital waveform. Since the charge/discharge current measuring section 90 can detect a high-frequency current, the digitizer 120 can acquire a digital waveform including high-frequency components.

The judging section 130 judges the acceptability of the device under test 200 based on the digital waveform of the load current measured by the digitizer 120. The judging section 130 may judge the acceptability of the device under test 200 based on whether a predetermined characteristic value in the digital waveform is within a predetermined allowable range. This characteristic value may be peak level, intervals between peaks, a comparison between a plurality of peak levels, rising time of the waveform, falling time of the waveform, duration of the waveform, duty ratio, frequency spectrum of the waveform, or any combination thereof.

The setting section 140 sets the gain of the differential circuit 92. The differential circuit 92 is an amplifier that amplifies the potential difference between the ends of the second detection resistor 91 by the set gain. For example, the setting section 140 may sequentially change the set gain of the differential circuit 92 to be a plurality of values, and the high-frequency current to be measured may be detected at each gain setting. At this time, the transmission path 20 is supplied with the same current each time the gain setting value is changed. When setting the gain of the differential circuit 92, a setting load may be connected to the transmission path 20 in place of the device under test 200.

The setting section 140 sets the gain of the differential circuit 92 such that the level of the current peak at a prescribed frequency detected for each gain setting is maximized. Since a normal amplification circuit changes the frequency characteristics according to the gain setting, the gain of the frequency to be measured might decrease even if the gain setting value is large. By measuring the digital waveform of the load current of the device under test 200 after performing the above setting, the gain can be set according to the frequencies at which the current peaks are to be measured.

As shown in FIG. 2, when the low-capacitance capacitor 48 is connected to the transmission path 20 between the device under test 200 and the intermediate capacitor 50, the load current calculating section 98 calculates the current flowing through the device under test 200 and the low-capacitance capacitor 48 based on the current I1 and the current I2. Since the time during which the charge/discharge current of the low-capacitance capacitor 48 flows is relatively short, the load current calculating section 98 may set the current flowing through the device under test 200 to be the sum of the current I1 and the current I2. Furthermore, the low-capacitance capacitor 48 may be a capacitor within the device under test 200.

As described above, by providing the intermediate capacitor 50 near the device under test 200 and calculating the sum of the charge/discharge current I2 of the intermediate capacitor 50 and the power supply current I1, the current consumed by the device under test 200 can be accurately measured. In other words, even when the power supply current I1 cannot quickly follow the fluctuation of the current consumed by the device under test 200, the charge/discharge current I2 that changes quickly is measured, thereby enabling accurate measurement of the current consumed by the device under test 200.

The power supply current measuring section 60 can be provided closer to the power supply 30 than the intermediate capacitor 50, and therefore the circuit design is simpler than a circuit design in which the power supply current measuring section 60 is provided on the test board 10. Instead of the power supply current measuring section 60, a measurement circuit housed in the power supply 30, such as the low current measuring section 32, can be used to measure the power supply current I1.

By using a semiconductor switch for the switch 52, the switch 52 can be easily provided to the test board 10, which has structural limitations such as the height of elements therein. Therefore, even when the test board 10 is provided with an intermediate capacitor 50 with a relatively high capacitance, the switch 52 can be provided to control whether the intermediate capacitor 50 is connected to the transmission path 20.

The power supply 30 may detect, via the detection line 42, the load current applied to the device under test 200. The power supply 30 controls the output voltage such that the detected load voltage remains at a prescribed amount. The detection line 42 may detect the voltage in the transmission path 20 on the device under test 200 side of the power supply current measuring section 60.

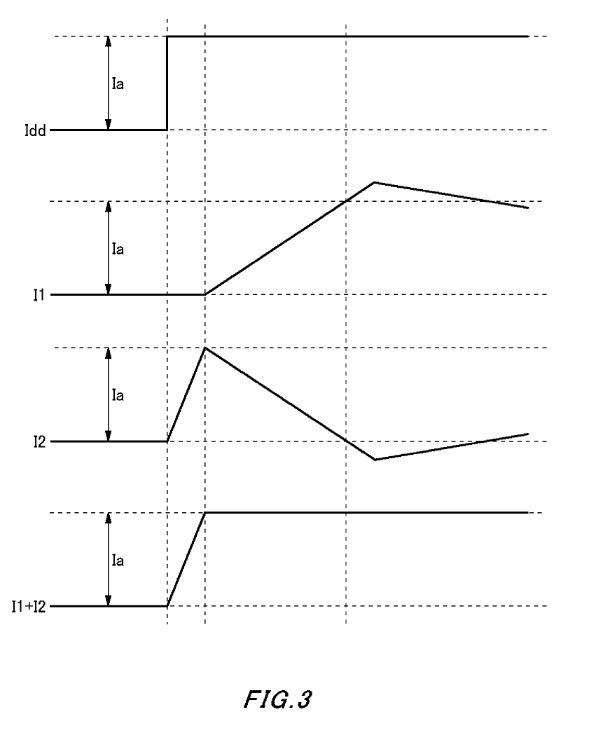

FIG. 3 shows an exemplary current I1 measured by the power supply current measuring section 60 and an exemplary current I2 measured by the charge/discharge current measuring section 90. In FIG. 3, the horizontal axis represents time and the vertical axis represents level. Furthermore, Idd in FIG. 3 represents the current consumed by the device under test 200.

As shown in FIG. 3, when the consumed current Idd of the device under test 200 changes suddenly, the power supply current I1 from the power supply 30 and the high-capacitance capacitor 44 cannot quickly follow this change. On the other hand, the charge/discharge current I2 from the intermediate capacitor 50 follows the consumed current Idd relatively quickly. Therefore, as shown in FIG. 3, the consumed current Idd of the device under test 200 can be accurately measured by calculating the sum of the power supply current I1 and the charge/discharge current I2.

In the circuit described in relation to FIG. 2, the first detection resistor 62 and the second detection resistor 91 are additionally provided to detect the current. Therefore, the fluctuation of the power supply voltage applied to the device under test 200 when the consumed current of the device under test 200 fluctuates increases according to the resistance values of the first detection resistor 62 and the second detection resistor 91.

The resistance value of the first detection resistor 62 is set as R1, the resistance value of the second detection resistor 91 is set as R2, and the maximum fluctuation amount of the consumed current Idd is set as I1. In this case, the maximum fluctuation ΔVmax in the power supply voltage applied to the device under test 200 due to the inclusion of the first detection resistor 62 and the second detection resistor 91 is Ia×(R1+R2).

The first detection resistor 62 and the second detection resistor 91 preferably have resistance values according to the allowable fluctuation amount for the power supply voltage applied to the device under test 200. For example, when the maximum fluctuation amount of the consumed current is 100 mA and the allowable value for the power supply fluctuation is 20 mV, the sum of the resistance values of the first detection resistor 62 and the second detection resistor 91 is set to be no greater than 200 mΩ(20 mV/100 mA) according to the above expression.

The current path of the power supply current I1 is an LCR series resonant circuit. Therefore, if the damping resistance of the series resonant circuit is not sufficiently smaller than the resistance component of the current path, charge/discharge current with large vibration occurs. This causes the measurement result of the power supply current I1 to include a charge/discharge current flowing to the intermediate capacitor 50 due to series resonance. To prevent this, the circuit shown in FIG. 2 measures the sum of the power supply current I1 and the charge/discharge current I2. Since the power supply current I1 and the charge/discharge current I2 each include the effect of the charge/discharge current due to series resonance, the effects of the charge/discharge current due to series resonance cancel each other out.

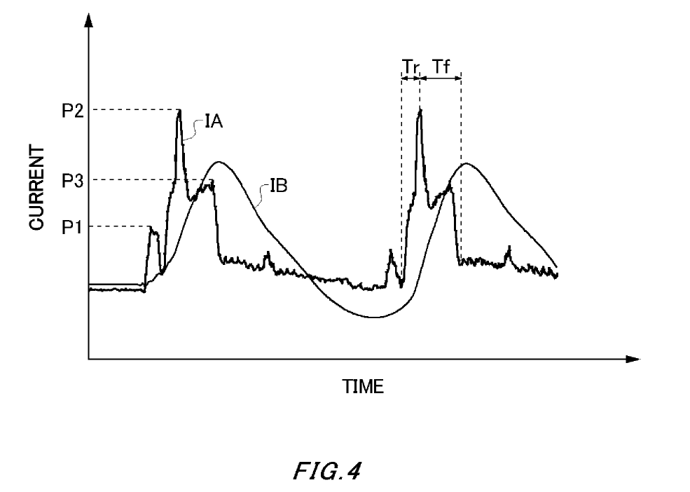

FIG. 4 shows a load current IA calculated by the load current calculating section 98 and a current IB output by the power supply 30, when the device under test 200 performs a read operation. The device under test 200 has a plurality of operational modes, which include a read operation for reading data from the device under test 200, a program operation for writing data to the device under test 200, and an erase operation for erasing data from the device under test 200. The device under test 200 may include a flash memory. As described above, the load current calculating section 98 can measure the load current IA whose frequency is higher than that of the current IB output by the power supply 30.

The digitizer 120 acquires the digital waveform of the load current IA. The digitizer 120 may acquire this digital waveform by sampling the load current IA according to a sampling clock input thereto.

The judging section 130 judges the acceptability of the device under test 200 based on whether a predetermined characteristic value in the digital waveform acquired by the digitizer 120 is within a predetermined allowable range. As show in FIG. 4, the judging section 130 may judge the acceptability of the device under test 200 based on (i) a ratio between levels P1, P2, and P3 of the current peaks in the digital waveform or (ii) the rising time Tr and the falling time Tf of the waveform, for example.

The judging section 130 may judge whether the device under test 200 is working properly by comparing a characteristic value of the digital waveform acquired by the digitizer 120 to a characteristic value of the current waveform obtained when the device under test 200 is operating properly. The load current IA detected by the digitizer 120 includes a frequency component that is higher than the frequency of the current IB output by the power supply 30, and so the judging section 130 can accurately judge whether the device under test 200 is correctly executing the prescribed operation.

When operating in each of the various operational modes, such as the mode for the read operation, the device under test 200 executes a plurality of specific operations from when the operation starts to when the operation ends. For example, upon receiving a read instruction, the device under test 200 sequentially executes a plurality of specific operations including acquiring address information, pre-charging a control line of a memory cell, reading data from the memory cell, and outputting the read data. The timing at which each specific operation is executed and the current consumed during each specific operation, for example, are determined according to the operational mode. Therefore, the by analyzing the load current IA that includes high-frequency components, the test apparatus 100 can judge whether the device under test 200 is operating correctly for each specific operation of the device under test 200.

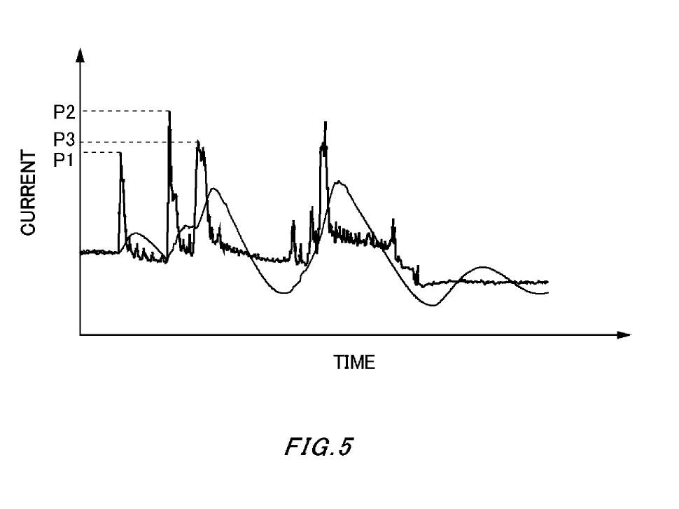

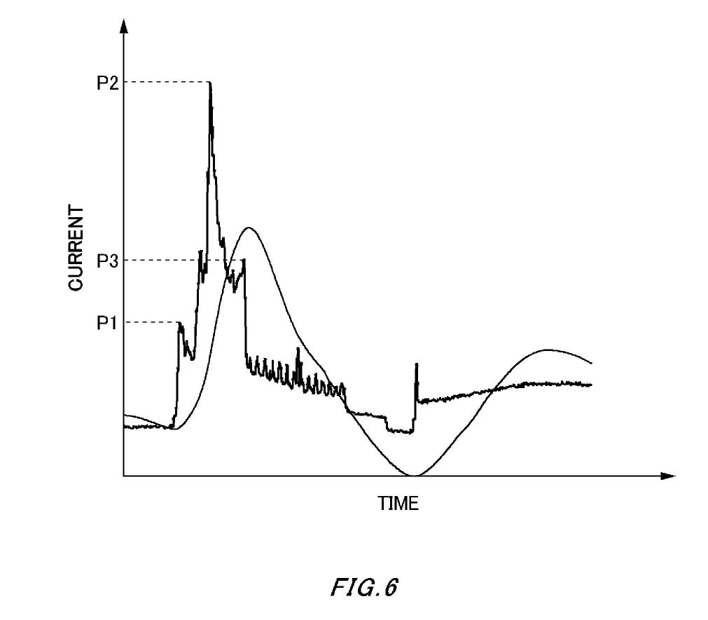

FIG. 5 shows a load current IA calculated by the load current calculating section 98 and a current IB output by the power supply 30, when the device under test 200 performs a program operation. FIG. 6 shows a load current IA calculated by the load current calculating section 98 and a current IB output by the power supply 30, when the device under test 200 performs an erase operation.

Since the specific operations performed by the device under test 200 differs for each operational mode of the device under test 200, the waveform of the load current IA of the device under test 200 differs for each operational mode of the device under test 200, as shown in FIGS. 4 to 6. The judging section 130 may change the allowable range of the comparison with the characteristic value of the load current IA for each operational mode of the device under test 200.

Since the load current IA detected by the digitizer 120 includes high-frequency components, this load current IA includes more information. Therefore, the characteristic value of the load current IA changes significantly for each operational mode of the device under test 200. Accordingly, by changing the allowable range for each operational mode, the test apparatus 100 can accurately judge whether the device under test 200 is operating correctly in each operational mode.

The test module 40 supplies the device under test 200 with instructions designating which operation to perform. The judging section 130 may receive these instructions from the test module 40 and identify the operational mode of the device under test 200. Instead, the judging section 130 may identify the operational mode of the device under test 200 based on a signal output by the device under test 200. The judging section 130 may identify the operational mode of the device under test 200 based on what is written in a header portion of data output by the device under test 200, for example. The judging section 130 determines the allowable range for the comparison with the characteristic value of the load current IA based on the identified operational mode.

The judging section 130 may judge whether there is a defect in any of the specific operations performed by the device under test 200. For example, the judging section 130 may judge whether there is a defect in any of the specific operations performed by the device under test 200 based on a position on a time axis at which a current peak falls outside the allowable range concerning peak levels, a ratio of a peak level to another current peak level, rising time, falling time, or duration of a peak.

The judging section 130 may judge the acceptability of the device under test 200 by calculating a frequency spectrum as the characteristic value of the load current IA. In this case, the judging section 130 performs a Fourier transform on the digital waveform within a predetermined measurement period. The starting point and ending point of this measurement period may be set by a user or the like, or may be set by the judging section 130 based on an output signal of the device under test 200.

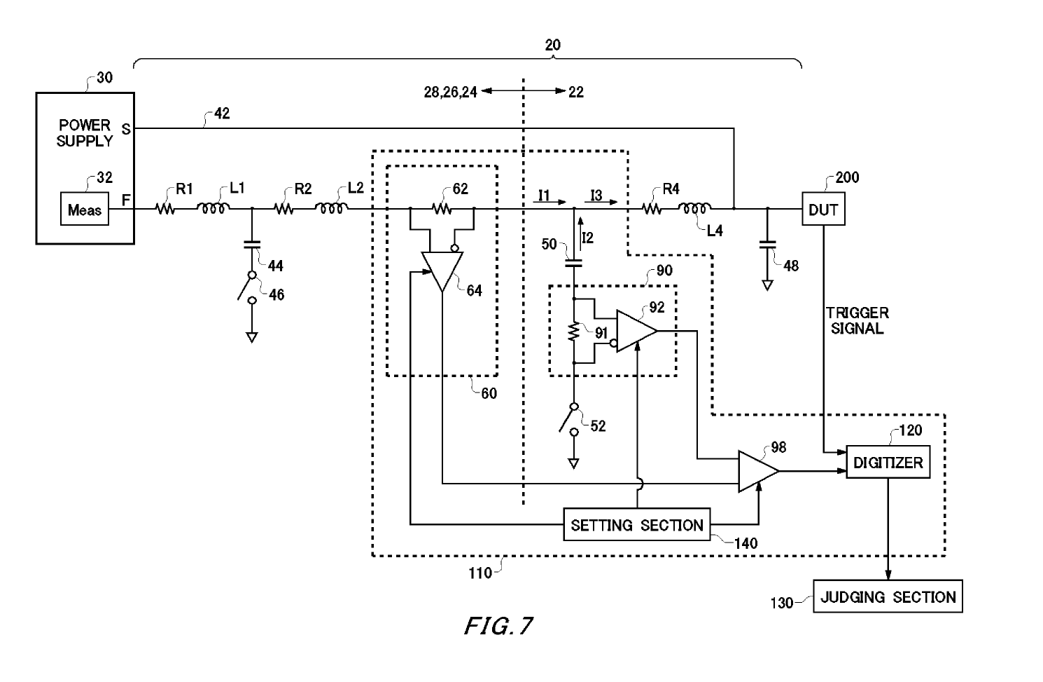

FIG. 7 shows an exemplary operation of the test apparatus 100. The judging section 130 of the test apparatus 100 according to the present embodiment sets the measurement period over which the digital waveform output by the digitizer 120 is measured, according to a trigger signal output by the device under test 200. The device under test 200 may output the trigger signal, which defines the starting point of the measurement period, to the judging section 130 according to the instructions input thereto for executing the prescribed operational mode. The device under test 200 may output the trigger signal before exiting a standby state in response to the instructions.

The judging section 130 may set the measurement period to be from the starting point defined by the trigger signal to a point when a prescribed time has passed therefrom. The judging section 130 may change the length of the measurement period according to the operational mode of the device under test 200. As a result, the judging section 130 can set a measurement period with an appropriate length for each operational mode having a different execution time.

The judging section 130 may change a delay time, which is from when the trigger signal is received to the starting point of the measurement period, according to the operational mode of the device under test 200. When measuring a frequency spectrum of the load current while the device under test 200 executes a prescribed specific operation, the judging section 130 may set the length and the starting point of the measurement period to correspond to the specific operation to be measured. The length and the starting point of the measurement period corresponding to the specific operation to be measured may be identified according to the operational mode of the device under test 200.

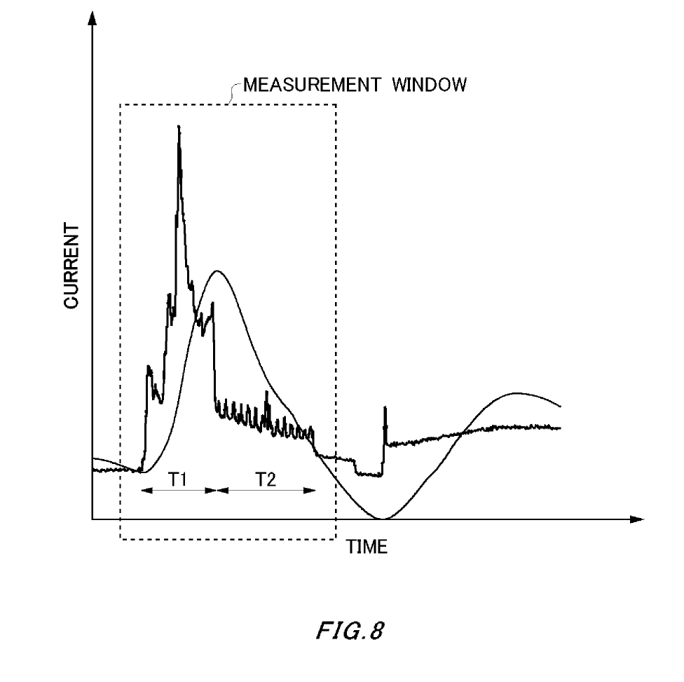

FIG. 8 shows a measurement period of the judging section 130. As described above, the judging section 130 measures the load current IA within a predetermined measurement period according to the trigger signal. By setting the length of the measurement period according to the execution time of the operational mode, a continuous current waveform from the start to the end of the operational mode can be measured.

When the device under test 200 performs a burst operation, such as burst reading or burst writing, the load current IA fluctuates during a prescribed period, as shown by the current waveform in the period T2. The judging section 130 may set the measurement period to correspond to the period T2. The period T2 during which the burst operation is executed can be determined according to the operational mode. The judging section 130 may calculate the frequency spectrum by performing a Fourier transform on the digital waveform of the load current IA in the period T2. The judging section 130 may judge the acceptability of the device under test 200 based on the amount of a noise component, which is outside of a prescribed frequency component such as the frequency of the burst operation, included in the calculated frequency spectrum.

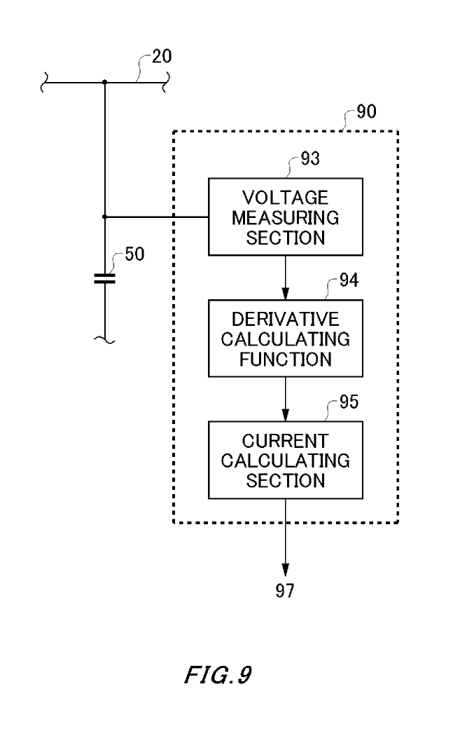

FIG. 9 shows another exemplary configuration of the charge/discharge current measuring section 90. The charge/discharge current measuring section 90 of the present embodiment includes a voltage measuring section 93, a derivative calculating section 94, and a current calculating section 95. The voltage measuring section 93 measures the voltage of the intermediate capacitor 50. The voltage measuring section 93 may measure a change over time of the voltage at a transmission path 20 side terminal of the intermediate capacitor 50.

The derivative calculating section 94 calculates a derivative value of the voltage measured by the voltage measuring section 93. The current calculating section 95 calculates the charge/discharge current of the intermediate capacitor 50 based on the derivative value calculated by the derivative calculating section 94. The current calculating section 95 may set the current value of the charge/discharge current of the intermediate capacitor 50 to be the derivative value of the voltage measured by the voltage measuring section 93. With this configuration, the charge/discharge current measuring section 90 can measure the charge/discharge current of the intermediate capacitor 50 without using the second detection resistor 91.

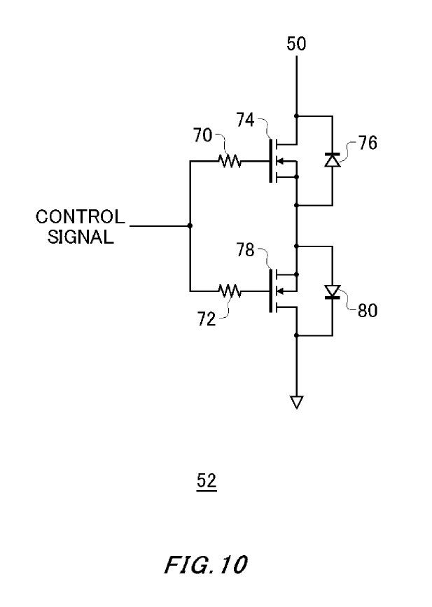

FIG. 10 shows an exemplary configuration of the switch 52. The switch 52 includes a transistor 74, a transistor 78, a diode 76, a diode 80, a resistor 70, and a resistor 72. The transistor 74 and the transistor 78 are arranged in series between the intermediate capacitor 50 and the ground potential. The transistor 74 and the transistor 78 receive a control signal in parallel via the resistor 70 and the resistor 72. The transistor 74 and the transistor 78 may have the same polarity.

The diode 76 is a parasitic diode that is formed between the source and drain of the transistor 74. The diode 80 is a parasitic diode that is formed between the source and drain of the transistor 78. In the present embodiment, the diode 76 is oriented in a forward direction from the ground potential toward the intermediate capacitor 50, and the diode 80 is oriented in a reverse direction from the intermediate capacitor 50 to the ground potential.

When the control voltage is level H, the intermediate capacitor 50 is connected to the ground potential via the transistor 74 and the transistor 78. When the control voltage is level L, each transistor is OFF and each diode has a reverse connection such that current does not flow, and so the intermediate capacitor 50 is disconnected from the ground potential. With this configuration, the switch 52 can be formed to be small and to have low power consumption.

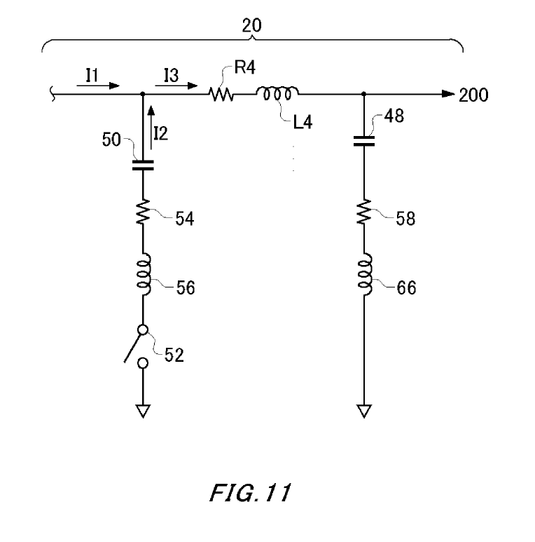

FIG. 11 shows another exemplary configuration of a circuit for measuring the current flowing through the transmission path 20. In FIG. 11, only a portion of this circuit is shown. The test apparatus 100 of the present embodiment further includes a damping resistor 54, in addition to the configuration described in FIG. 2. The damping resistor 54 may function as the second detection resistor 91. The inductor 56 represents the inductance component in series with the intermediate capacitor 50 and located between the transmission path 20 and the ground potential. The inductor 66 and the resistor 58 represent the inductance component and the resistance component that are in series with the low-capacitance capacitor 48 and located between the transmission path 20 and the ground potential.

The system that connects the intermediate capacitor 50 to the low-capacitance capacitor 48 is formed by a series resonant circuit. As a result, the current flowing through the device under test 200 is resonated. Therefore, the test apparatus 100 of the present embodiment includes the damping resistor 54 to decrease the current resonance.

The damping resistor 54 is connected in series with the intermediate capacitor 50, between the transmission path 20 and the ground potential, and has a resistance value corresponding to the capacitance values of the intermediate capacitor 50 and the low-capacitance capacitor 48. More specifically, the damping resistor 54 is set according to the impedance in the resonance frequency of the composite inductance component L and the composite capacitance component C of the series resonant circuit.

The resonance frequency of this series resonant circuit can be calculated based on the composite inductance component L and the composite capacitance component C of this circuit, using the expression 1/(2π×(LC)^{0.5}). The resistance value of the damping resistor 54 may be determined according to the impedance of the composite inductance component L and the composite capacitance component C of the resonance frequency. The inductance of the resonance frequency is (L/C)^{0.5}. The resistance value of the damping resistor 54 may be set such that the composite resistance value of the series resonant circuit is 2×(L/C)^{0.5.}

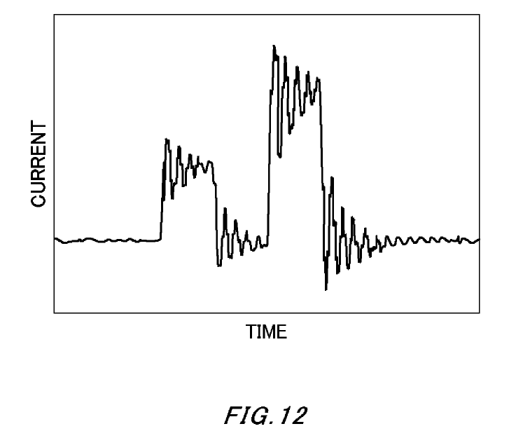

FIG. 12 shows the current flowing through the resistance component R4 in the current path to the device under test 200 when the damping resistor 54 has a resistance value approximately equal to that of the resistor 58. In the present embodiment, the inductance component L4, the inductance of the inductor 56, and the inductance of the inductor 66 are each set to 0.5 nH, the capacitance of the intermediate capacitor 50 is set to 2 μF, the capacitance of the low-capacitance capacitor 48 is set to 0.2 μF, the resistance value of the resistance component R4 is set to 2 mΩ, and the resistance values of the damping resistor 54 and the resistor 58 are each set to 5 mΩ. In this case, a large resonance component is included in the current flowing through the intermediate capacitor 50 and the low-capacitance capacitor 48.

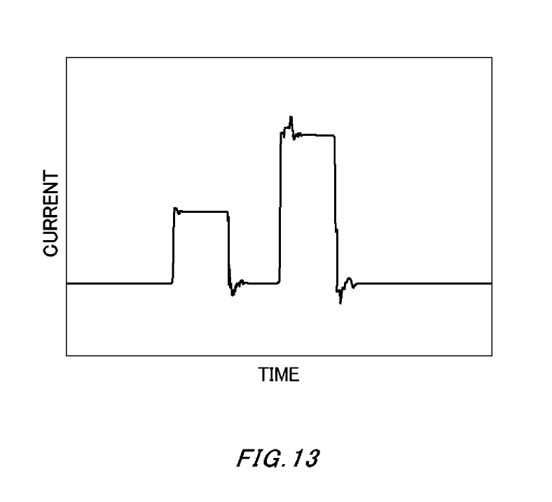

FIG. 13 shows the current flowing through the resistance component R4 in the current path to the device under test 200 when the damping resistor 54 has a resistance value that is 20 times greater than that of the resistor 58. The characteristic values of the elements in the present embodiment are the same as those described in FIG. 12, except that the resistance value of the damping resistor 54 is 85 mΩ. As shown in FIG. 13, the damping resistor 54 can decrease the resonance component of the current flowing though the resistance component R4 in the current path to the device under test 200. The damping resistor 54 may have a resistance value grater than that of the resistor 58.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
a power supply that generates power supplied to the device under test;
a transmission path that transmits the power generated by the power supply to the device under test;
a current measuring section that measures a digital waveform of load current supplied to the device under test via the transmission path, the digital waveform including a frequency component higher than a frequency corresponding to a product of an inductance component of the power supply and a capacitance component between the transmission path and a ground potential; and
a judging section that judges acceptability of the device under test based on the digital waveform of the load current measured by the current measuring section.

2. The test apparatus according to claim 1, further comprising:
an intermediate capacitor provided between the transmission path and the ground potential; and
a charge/discharge current measuring section that measures charge/discharge current of the intermediate capacitor, wherein
the current measuring section measures the load current based on the charge/discharge current measured by the charge/discharge current measuring section.

3. The test apparatus according to claim 2, further comprising a power supply current measuring section that measures current flowing through the transmission path on the power supply side of the intermediate capacitor, wherein
the current measuring section measures the load current based on a sum of the current measured by the power supply current measuring section and the current measured by the charge/discharge current measuring section.

4. The test apparatus according to claim 3, wherein
the judging section judges the acceptability of the device under test based on whether a predetermined characteristic value of the digital waveform is within a predetermined allowable range.

5. The test apparatus according to claim 4, wherein
the judging section judges the acceptability of the device under test based on a characteristic value that is a ratio between a plurality of levels of peaks in the digital waveform of the load current.

6. The test apparatus according to claim 4, wherein
the judging section judges the acceptability of the device under test based on a characteristic value that is rising time or falling time of the digital waveform of the load current.

7. The test apparatus according to claim 4, wherein
the judging section judges the acceptability of the device under test based on a characteristic value that is a frequency spectrum of the load current within a predetermined measurement period.

8. The test apparatus according to claim 4, wherein
the device under test has a plurality of operational modes, and
the judging section changes the allowable range for each operational mode.

9. The test apparatus according to claim 7, wherein
the judging section determines the measurement period according to a trigger signal output by the device under test.

10. The test apparatus according to claim 9, wherein
the device under test has a plurality of operational modes, and
the judging section changes the measurement period for each operational mode.

11. The test apparatus according to claim 3, further comprising a high-capacitance capacitor that has a higher capacitance than the intermediate capacitor and that is provided between the ground potential and the transmission path at a position closer to the power supply than the intermediate capacitor.

12. The test apparatus according to claim 11, further comprising a low-capacitance capacitor that has a lower capacitance than the intermediate capacitor and that is provided between the ground potential and the transmission path at a position closer to the device under test than the intermediate capacitor.

13. The test apparatus according to claim 12, wherein
the current measuring section calculates current flowing through the device under test and the low-capacitance capacitor based on the sum of the current measured by the power supply current measuring section and the current measured by the charge/discharge current measuring section.

14. The test apparatus according to claim 12, wherein
the intermediate capacitor is connected to the transmission path at a position whereby a distance between the low-capacitance capacitor and the intermediate capacitor is less than a distance between the high-capacitance capacitor and the intermediate capacitor.

15. The test apparatus according to claim 12, further comprising a damping resistor that is provided in series with the intermediate capacitor between the transmission path and the ground potential and that has a larger resistance value than a resistance component in series with the low-capacitance capacitor between the transmission path and the ground potential.

16. The test apparatus according to claim 14, further comprising a test board that contacts the device under test, wherein
the low-capacitance capacitor and the intermediate capacitor are provided on the test board.

17. The test apparatus according to claim 16, further comprising a connector that is provided on the transmission path and that electrically connects the test board to the power supply, wherein
the high-capacitance capacitor is connected to the transmission path on the power supply side of the connector.

18. The test apparatus according to claim 17, wherein
the power supply current measuring section measures the current flowing through the transmission path between the connector and the high-capacitance capacitor.

19. The test apparatus according to claim 18, wherein
the power supply current measuring section includes:
a first detection resistor that is provided on the transmission path on the power supply side of the connector; and
a first potential difference detecting section that detects a potential difference between ends of the first detection resistor, and
the charge/discharge current measuring section includes:
a second detection resistor that is provided between the intermediate capacitor and the ground potential; and
a second potential difference detecting section that detects a potential difference between ends of the second detection resistor.

20. The test apparatus according to claim 17, wherein
the power supply current measuring section includes:
a first detection resistor that is provided on the transmission path on the power supply side of the connector; and
a first potential difference detecting section that detects a potential difference between ends of the first detection resistor, and
the charge/discharge current measuring section includes:
a voltage measuring section that measures voltage of the capacitor;
a derivative calculating section that calculates a derivative value of the voltage measured by the voltage measuring section; and
a current calculating section that calculates the charge/discharge current of the capacitor based on the derivative value calculated by the derivative calculating section.
